(19) United States
(12) Patent Application Publication
(10) Pub. No.: US 2024/0377443 A1
(43) Pub. Date: Nov. 14, 2024

(54) MODULAR ANTENNA ARRAY

(71) Applicant: Sykno GmbH, Erlangen (DE)

(72) Inventors: Benedict SCHEINER, Erlangen (DE); Fabian MICHLER, Erlangen (DE); Torsten REISSLAND, Erlangen (DE); Konstantin LOMAKIN, Erlangen (DE); Andreas HOFMANN, Erlangen (DE); Mark SIPPEL, Fürth (DE)

(21) Appl. No.: 18/653,679

(22) Filed: May 2, 2024

(30) Foreign Application Priority Data
May 8, 2023 (DE) 10 2023 111 906.0

(51) Int. Cl. G01R 29/08

(52) U.S. Cl. CPC G01R 29/0871; G01R 29/0878

(57) ABSTRACT

The present disclosure relates to a modular antenna array, in particular a modular MIMO antenna array, for evaluating different antenna array characteristics, and comprises a printed circuit board with a chipset for transmitting and/or receiving a high-frequency electromagnetic wave, and at least one unbundling component for mounting on the printed circuit board to guide the electromagnetic wave emitted from the printed circuit board to a transfer point of the unbundling component and/or to guide the electromagnetic wave received at a transfer point of the unbundling component to the printed circuit board.

### CROSS REFERENCE TO RELATED APPLICATION

The present application claims priority to German Patent Application No. 10 2023 111 906.0 filed on May 8, 2023. The entire contents of the above-listed application are hereby incorporated by reference for all purposes.

### TECHNICAL FIELD

The present disclosure relates to a modular antenna array, in particular a modular MIMO antenna array.

### BACKGROUND

MIMO stands for Multiple Input-Multiple Output and refers to a principle in radio technology in which multiple transmitting and receiving elements are used in order to achieve an additional gain in information. In a radar system, this makes it possible to achieve angular resolutions which, however are dependent on the type and arrangement of the individual radiators used, amongst other factors.

### SUMMARY

Antennas and the radars that can be generated with them have become increasingly widespread in recent years, with the desire to have vehicles drive autonomously in the future being a driving factor behind this. Many experts consider it essential for vehicles to scan their surroundings with the aid of radars in order to ensure that their surroundings are detected as accurately as possible and to enable them to choose a collision-free route.

However, not only the localization of objects, but also the communication of data is carried out with the help of antenna arrays, where a specific antenna characteristic can be advantageous.

In order to achieve the best possible antenna configuration for the underlying task during the development phase of an antenna array, manufacturers of positioning or communication chipsets offer so-called evaluation platforms with several different predefined antenna configurations, each of which specifies the radiation or reception characteristics of the overall system.

Antenna configurations that deviate from this require the development of application-specific systems. Typical evaluation platforms consist of a combination of several circuit boards that have to be plugged into each other, for example a baseband/supply board and a high-frequency board. In order to adjust the radiation characteristics, it is therefore not necessary to replace the entire system, but only the high-frequency board with the antennas on it. Although this means that the baseband/supply board can be reused, the components of the high-frequency board have to be reconfigured, purchased and soldered, which is costly and time-consuming. The evaluation of different antenna characteristics by using different configurations of antenna arrays is therefore extremely complex and cost-intensive to implement.

One such implementation known from the prior art is marketed by Infineon, for example, under the name “BGT60ATR24C shield”, wherein the high-frequency board “BGT60ATR24C shield” with antennas arranged on it can be plugged onto a baseband board, so that a further antenna array with a different IC is obtained.

It is the object of the present disclosure to provide a modular antenna array which at least partially overcomes the disadvantages mentioned above. This object is achieved by means of a modular antenna array as described herein.

According to the disclosure, a modular antenna array, in particular a modular MIMO antenna array, for evaluating different antenna array characteristics is provided, comprising a printed circuit board with a chipset for transmitting and/or receiving a high-frequency electromagnetic wave, and at least one unbundling component for mounting on the printed circuit board to guide the electromagnetic wave emitted from the printed circuit board to a transfer point of the unbundling component and/or to guide the electromagnetic wave received at a transfer point of the unbundling component to the printed circuit board. If several unbundling components are present, for example, at least one can be provided for Tx and at least one for Rx, i.e. at least one for transmitting and at least one for receiving.

The transfer point of the unbundling component can be configured in such a way that an electromagnetic wave can also be emitted or received. However, it can also be provided that the transfer point of the unbundling component outputs the electromagnetic wave to a further component interacting with the unbundling component or receives an electromagnetic wave from the further component.

In principle, the array according to the disclosure enables modular communication and radar systems with changeable antenna positions and-types. The same printed circuit board always serves as the basis since a chipset is already provided there to transmit and/or receive a high-frequency electromagnetic wave. In contrast to the prior art, it is therefore no longer necessary to provide further logic modules for generating a high-frequency electromagnetic wave in the additional element to be placed on the circuit board, so that it is also no longer necessary to provide electrical connections between the two interacting components.

According to the disclosure, it is provided that the printed circuit board already has all the components required for emitting or receiving a high-frequency electromagnetic wave, so that the unbundling component interacting with the printed circuit board only serves to define the final emission position of the at least one electromagnetic wave.

For this purpose, the unbundling component comprises at least one conductor for the at least one electromagnetic wave generated or to be received by the printed circuit board, in order to guide a respective electromagnetic wave to a predetermined emission location (transfer point) of the unbundling component or to guide it from a predetermined reception location (transfer point) of the unbundling component to the printed circuit board.

According to the present disclosure, the evaluation of different antenna types or antenna characteristics is limited to the attachment of differently configured unbundling components, each of which has a specific antenna configuration and does not have a chipset or logic module. A unbundling component merely has at least one conductor for an electromagnetic wave, for example a waveguide or a dielectric waveguide.

According to an advantageous modification of the present disclosure, it may be provided that the modular antenna array further comprises a transceiver component for mounting on the unbundling component in order to receive an electromagnetic wave originating from the printed circuit board from the transfer point of the unbundling component and to radiate it via at least one antenna or to feed it back via a coupling element, and/or to transmit an electromagnetic wave received by the transceiver component by means of at least one antenna or fed back by means of at least one coupling element to the transfer point of the unbundling component for onward transmission to the printed circuit board.

Accordingly, according to the present disclosure, it may be provided that the modular antenna array comprises, in addition to the printed circuit board and the unbundling component, a transceiver component which is to be placed on the unbundling component. The printed circuit board with its chipset takes over the complete processing of an electromagnetic wave received or to be transmitted and emits it in the final, high-frequency wave range or picks up the received high-frequency wave. The attached unbundling component picks up the electromagnetic wave emitted by the printed circuit board with its at least one conductor and forwards it to at least one predetermined transfer point. In turn, a transceiver component is placed on the unbundling component, which receives the electromagnetic wave from the at least one transfer point of the unbundling component and emits it, for example, via a specific antenna configuration. However, the transceiver component can also comprise at least one coupling element in order to connect a first transfer point to a second transfer point of the unbundling component via a line.

By providing the unbundling component, it is therefore possible to evaluate different transceiver components, wherein only one respective unbundling component needs to be provided for a specific printed circuit board, which is configured to guide the electromagnetic waves emitted by the printed circuit board to predefined transfer points. It is therefore possible to provide a wide variety of transceiver components and, for evaluation with a corresponding printed circuit board (which contains a specific chipset), it is only necessary to provide a unbundling component that is matched to the printed circuit board. This then connects the various transceiver components to the PCB. This also makes it much easier to evaluate new (three-dimensional) antenna types.

A unbundling component describes line structures that establish the high-frequency connection between the printed circuit board and radiating antenna elements (which can be arranged on the unbundling component itself or on a transceiver element that can be attached to the unbundling component). This connection usually represents a spatial expansion of closely spaced conductive paths to antenna elements or array antennas (an antenna consisting of several individual radiators combined either in the analog or digital domain) arranged in the plane or three-dimensionally distributed. The unbundling network is typically a three-dimensional structure. The cable lengths in the unbundling network should have defined lengths.

The described array also enables the characterization of 3D-printed antennas by placing them on the unbundling component located on the circuit board in the form of correspondingly configured transceiver components 6 after production and measuring their radiation behavior. As no network analyzer is required and no screws are needed, a large number of antennas can be tested using this method.

According to an optional modification of the present disclosure, it is provided that each length of a plurality of conductors of the unbundling component is equal to, differs by a multiple of a full wavelength, a half wavelength and/or a quarter wavelength of the high-frequency electromagnetic wave generated by the circuit board. The same applies to the total length of the routing path of the unbundling component and the transceiver component.

Furthermore, according to the present disclosure, it may be provided that the printed circuit board and the unbundling component in a mounted state comprise an alignment means which defines a predetermined positioning of the unbundling component relative to the printed circuit board, wherein the alignment means is at least one through-hole in the unbundling component and the printed circuit board, which in a mounted state are aligned with one another and through which a dowel pin can be inserted.

The alignment means ensures that the two interacting components are joined together in such a way that the at least one electromagnetic wave generated by the printed circuit board is transferred to a respective conductor of the unbundling component with the lowest possible attenuation.

According to a further advantageous embodiment of the present disclosure, it may be provided that the unbundling component in a mounted state on the printed circuit board, together with the printed circuit board and/or the transceiver component, comprises an alignment means which defines a predetermined position of the transceiver component relative to the unbundling component, wherein the alignment means is at least one through-hole in the unbundling component and the transceiver component, which are aligned with each other and through which a dowel pin can be inserted, such that the through-hole is aligned with a through-hole in the printed circuit board.

Of course, an alignment means is also advantageous for the alignment of the transceiver component with respect to the unbundling component, wherein in an arrangement of printed circuit board, unbundling component and transceiver component, a respective hole in each of the components or a corresponding dowel pin in such a hole ensures the correct alignment of the multiple components in a simple manner. It is clear to the skilled person that there are several possible implementations of alignment means for correctly aligning the various components, wherein only the aligned arrangement of several through-holes in the individual components, into which, for example, a dowel pin can be inserted to fix the components, is shown here as an example.

Optionally, according to the disclosure, it can be provided that at least one printed circuit board antenna for transmitting and/or receiving is arranged in a housing of the chipset, as a chipset antenna integrated into the chipset in the form of a waveguide junction.

According to the disclosure, it is therefore possible for the chipset arranged on the printed circuit board to have at least one integrated antenna for emitting a high-frequency electromagnetic wave. It may be provided that the input of the conductor of the unbundling component on the printed circuit board side is directed directly to the chipset in order to introduce the high-frequency electromagnetic wave into the unbundling component.

Optionally, according to the disclosure, it can also be provided that at least one printed circuit board antenna for transmitting and/or receiving is arranged next to a housing of the chipset in the printed circuit board, as a printed circuit board interface in the form of a waveguide junction.

According to such an implementation, the printed circuit board has a connection to the chipset, wherein at least one antenna for emitting a high-frequency electromagnetic wave is provided at a region of the connection distal from the printed circuit board.

An unbundling component interacting with the printed circuit board therefore comprises an input of the conductor on the printed circuit board side, which is directed directly to the printed circuit board and not to the chipset located there.

According to an advantageous modification of the present disclosure, it may be provided that the chipset is configured to perform processing of an electromagnetic wave to be received and/or an electromagnetic wave to be transmitted in the radio frequency range and in the baseband range.

Furthermore, it may be provided that the chipset is at least one radar or communication chipset and/or that supply electronics for operating the chipset are arranged on the printed circuit board.

According to the disclosure, it can therefore be provided that the printed circuit board with its chipset located thereon does not require any further logic components in order to generate a high-frequency electromagnetic wave or to process its reception.

According to a further advantageous embodiment of the present disclosure, it may be provided that the unbundling component and/or the transceiver component is/are manufactured by means of a 3D printing process, an injection molding process, a die casting process and/or a milling process, wherein a plastic material forms the base material for the manufacturing process.

In particular, the use of a plastic material as the base material for the manufacturing process enables the rapid production of a unbundling component or a transceiver component, as 3D printing processes using plastic material are readily available on the market and have already proven their worth. In order to produce a waveguide of a unbundling component, for example, which has been produced using a 3D printing process, it is advisable to metallize the element initially printed with plastic material. This creates conductivity for electromagnetic waves, making the process significantly faster and cheaper than a milling process for blocks made entirely of metal.

Manufacturing processes such as metallized 3D printing of waveguide-based waveguides, which are configured for very high operating frequencies and cause only minimal losses, make it possible to compare the same system with different antenna types and arrangements. These manufacturing processes are also characterized by fast prototype production.

According to the disclosure, it can therefore be provided that the unbundling component and/or the transceiver component comprises metallized components, or is metallized.

During metallization, a metal layer is typically applied to a non-metallic base body in order to obtain the advantageous properties of a metallic surface. As metallization is usually carried out using a wet chemical process, the presence of complex structures, e.g. in the case of angled waveguides inside a braiding component, is not a problem.

According to an advantageous embodiment of the present disclosure, it may be provided that the transceiver component is configured to receive an electromagnetic wave originating from the printed circuit board from the unbundling component and to couple it back to the unbundling component, by connecting a plurality of transfer points of the unbundling component to a waveguide.

Further according to the present disclosure, it may be provided that the transceiver component is configured to receive an electromagnetic wave originating from the circuit board from the unbundling component and to radiate it via an antenna aperture, wherein the transceiver component comprises a plurality of antenna apertures which are not arranged in a common plane to form a 3D antenna.

In the prior art evaluation platforms available to date, the antennas are generally integrated into the PCB as planar elements. This means that they cannot be exchanged or their position varied. Changing the antenna types and/or positions therefore requires a new design and the production and assembly of the entire PCB, which results in high costs and a large amount of time.

Optionally, according to the disclosure, it can be provided that the unbundling component for guiding the electromagnetic wave comprises at least one waveguide, wherein the unbundling component for guiding a plurality of electromagnetic waves originating from the printed circuit board comprises a plurality of waveguides whose conduction channels in the unbundling component are not connected to one another.

According to the disclosure, it may be provided that a separate conductor, in particular a waveguide, is provided for each electromagnetic wave emitted by the printed circuit board.

According to an optional embodiment of the present disclosure, it may be provided that the unbundling component is configured to unbundle the plurality of electromagnetic waves emitted from the printed circuit board in a first specific area region and direct them to a second specific area region which is larger in area than the first specific area region.

According to the disclosure, it can also be provided that the printed circuit board is configured to generate a clock signal and pass it on to the unbundling component, in particular via a waveguide provided in the unbundling component for passing it on to a component that can be attached to the unbundling component.

The disclosure also relates to an evaluation board comprising a modular antenna array according to one of the above aspects.

### BRIEF DESCRIPTION OF THE FIGURES

Further features, details and advantages of the disclosure will become apparent from the following description of the figures. The Figures show in:

FIG. 1: a schematic sectional view of a modular antenna array according to the disclosure with printed circuit board and unbundling component, and

FIG. 2: a schematic view of a modular antenna array according to the disclosure with printed circuit board, unbundling component and several transceiver components,

### DETAILED DESCRIPTION

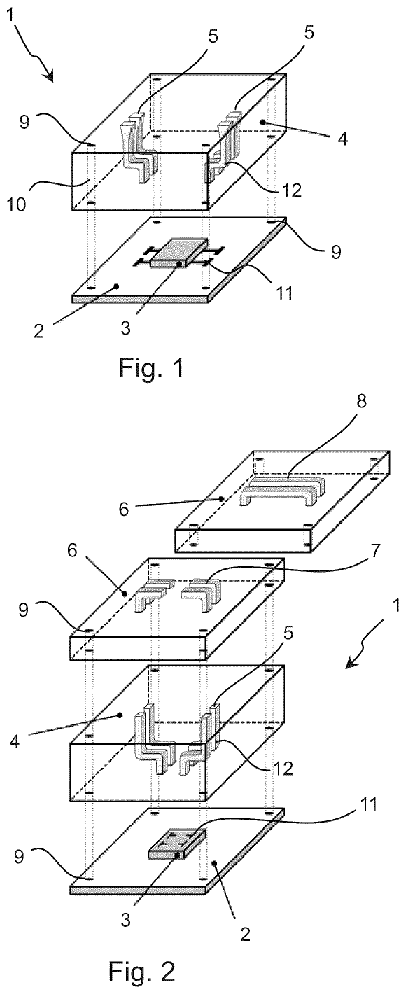

FIG. 1 shows a representation of a modular antenna array 1 according to the disclosure, in which the printed circuit board 2 is provided with a chipset 3 which is configured to generate an electromagnetic wave in a high-frequency range or to receive and process such a wave.

Above this, in a state raised from the printed circuit board 2, an unbundling component 4 is shown, which serves to connect the chipset 3 located on the printed circuit board 2 to one or more antenna elements. According to the disclosure, it may also be provided that the transfer points marked with the reference character 5 are antenna elements, so that the electromagnetic wave is emitted or received by the unbundling component 4.

The unbundling component 4 typically (but not limited to) guides the electromagnetic wave using waveguides 12, for example of rectangular cross-section. The antenna(s) 5 may be integrated into the at least one unbundling component 4 cooperating with the printed circuit board 2, for example as a radiating aperture of an open waveguide 12, or may be placed on one or more further components (for example on the transceiver component 6 described in more detail below).

In addition, an alignment means 9 is provided for the correct alignment of the unbundling component 4 with respect to the printed circuit board 2, which is implemented, for example, with the through-holes 10 shown and a corresponding dowel pin, which is inserted into the through-hole of the unbundling component 4 and the printed circuit board 2. Thus, if the unbundling component 4 is placed on the printed circuit board 2 and the two components 2, 4 are correctly aligned with each other, the waveguide 12 directed towards the printed circuit board 2 will be arranged on the printed circuit board 2 in such a way that an electromagnetic wave emitted by the printed circuit board 2 or the chipset 3 propagates in a respective waveguide 12 provided for this purpose.

FIG. 2 shows a further embodiment of the present disclosure, in which the unbundling is partially or completely outsourced into a component, the unbundling component 4, to which a transceiver component 6 is applied. The transceiver component 6 can also contain an unbundling, but does not have to.

By further providing a transceiver component 6, different types of antennas 7 can now be analyzed in a simple manner, as this only requires appropriately configured transceiver components 6, which can then simply be placed on the unbundling component 4. The characteristics of the back-coupling of emitted electromagnetic waves can also be investigated or analyzed with the aid of a transceiver component, which then comprises at least one coupling element 8 instead of radiating antennas, for example, which connects two different transfer points 5 of the unbundling component 4.

The unbundling component 4, as well as the transceiver component 6, can be milled from metal, manufactured by casting from metal or plastic material, or 3D-printed, for example. Dielectric structures are also possible.

Since the position and type of the antennas 5, 7 used determine decisive system properties such as the spatial area covered by the system, the overall system 1 can be casily adapted to different application scenarios by replacing the unbundling component 4 or the transceiver component 6 using the array described. This fact is particularly useful when evaluating modular MIMO antenna arrays, e.g. in communication and radar systems, and the chipsets contained therein in different application scenarios, as they can be replaced compared to the prior art without having to modify the underlying circuit board 2 with the chipset 3.

The antenna array 1 comprises one or more radar or communication chipsets 3 as well as the other components required for the system, all of which are located on the printed circuit board 2. So-called PCB antennas 11 can be arranged on the PCB 2, which are located in the housing of the chipset 3 (as shown in FIG. 2) or are present as a PCB interface (as shown in FIG. 1). The unbundling component 4 is applied to the printed circuit board 2, which guides the electromagnetic wave from the printed circuit board antennas 11 or the waveguide transitions 11 integrated in the chipset 3 to the radiating aperture, thereby spatially equalizing it. Waveguides 12 are typically used as waveguides, although other types of waveguides (for example dielectric waveguides) are also covered by the disclosure.

The object of the array is to make an overall system, which is intended to serve a positioning or communication purpose based on electromagnetic waves, modular and flexible in terms of the antenna types and arrangements used, so that these can be changed easily.

According to a further embodiment not shown in the figures, further components, such as a printed circuit board, can be mounted on the transceiver component 6 according to the disclosure in order to enable additional antenna types.

For evaluation purposes, the transceiver component 6 can be provided with waveguide-based coupling components 8, in which the electromagnetic wave received by the unbundling component 4 is not radiated, but coupled back. Such a component 8 is shown in FIG. 2 next to a transceiver component 6, which is provided with antenna elements 7.

The entire antenna array 1 has a modular structure and all sub-components can be combined as required, where appropriate. Consequently, different antenna types and arrangements can be realized on a printed circuit board 2 by exchanging the attached components (unbundling component 4 or transmit/receive component 6). The transmitting side (Tx) and the receiving side (Rx) can contain different unbundling components. In extreme cases, each antenna can be a separate component.

The individual components can be aligned and fixed in place with the aid of an alignment means 9, e.g. holes 10 that are aligned with each other and have dowel pins inserted in them.

According to a further embodiment of the disclosure, it may be advantageous to distribute a clock signal (e.g. local oscillator) in the waveguide for cascading several systems or for evaluating an overall system consisting of cascaded individual systems. This at least one waveguide to which the clock signal is applied can, for example, be integrated into the unbundling component. This allows the modular system to be flexibly expanded with additional chipsets or transmit and/or receive antennas. This is then done, for example, in such a way that a further chipset on a further printed circuit board can be synchronized using the clock signal. According to the disclosure, it is therefore possible to interconnect several printed circuit boards 2 with a chipset 3 arranged on each, wherein the clock signal is fed from a clocking chipset into a waveguide of the unbundling component 4 and the non-clocking chipset receives the clock pulse via the waveguide of the unbundling component 4 and synchronizes itself to this. This enables a significantly more complex antenna array, which can nevertheless be set up in a simple manner, as the individual components do not require an electrical connection to each other, but communicate using waveguides, in particular hollow waveguides.

This significantly simplifies the evaluation of complex antenna geometries.

### LIST OF REFERENCE CHARACTERS

1 modular antenna array
2 printed circuit board
3 chipset
4 unbundling component
5 transfer point
6 transceiver component
7 antenna | antenna aperture
8 coupling element
9 alignment means
10 through-holc
11 printed circuit board antenna
12 hollow guide | waveguide

1. Modular antenna array for evaluating different antenna array characteristics, comprising:
a printed circuit board with a chipset for transmitting and/or receiving a high-frequency electromagnetic wave,
at least one unbundling component for placing on to the printed circuit board in order to guide the electromagnetic wave emitted by the printed circuit board to a transfer point of the unbundling component and/or to guide the electromagnetic wave received at a transfer point of the unbundling component to the printed circuit board.

2. Modular antenna array according to claim 1, further comprising a transceiver component for placing on to the unbundling component in order to receive an electromagnetic wave originating from the printed circuit board from the transfer point of the unbundling component and to emit it via at least one antenna or to couple it back via a coupling element, and/or to transmit an electromagnetic wave received by the transceiver component by means of at least one antenna or fed back by means of at least one coupling element to the transfer point of the unbundling component for onward transmission to the printed circuit board.

3. Modular antenna array according to claim 1, wherein the printed circuit board and the unbundling component in a mounted state have an alignment means which defines a predetermined position of the unbundling component with respect to the printed circuit board.

4. Modular antenna array according to claim 2, wherein the unbundling component in a placed-on state on the printed circuit board together with the printed circuit board and/or the transceiver component has an alignment means which defines a predetermined position of the transceiver component with respect to the unbundling component.

5. Modular antenna array according to claim 1, wherein at least one printed circuit board antenna for transmitting and/or receiving is arranged in a housing of the chipset.

6. Modular antenna array according to claim 1, wherein at least one printed circuit board antenna for transmitting and/or receiving is arranged next to a housing of the chipset in the printed circuit board.

7. Modular antenna array according to claim 1, wherein the chipset is configured to perform processing of an electromagnetic wave to be received and/or an electromagnetic wave to be transmitted in the high frequency range and in the baseband range.

8. Modular antenna array according to claim 1, wherein the chipset is at least one radar or communication chipset, and/or wherein supply electronics for operating the chipset are arranged on the printed circuit board.

9. Modular antenna array according to claim 2, wherein the unbundling component and/or the transceiver component is/are manufactured by means of a 3D printing process, an injection molding process, a die casting process and/or a milling process.

10. Modular antenna array according to claim 2, wherein the unbundling component and/or the transceiver component comprises metallized components or is metallized.

11. Modular antenna array according to claim 2, wherein the transceiver component is configured to receive an electromagnetic wave originating from the printed circuit board from the unbundling component and to couple it back to the latter by means of a coupling element, by connecting multiple transfer points of the unbundling component to a waveguide.

12. Modular antenna array according claim 2, wherein the transceiver component is configured to receive an electromagnetic wave originating from the printed circuit board from the unbundling component and to radiate it via an antenna aperture, wherein the transceiver component comprises a plurality of antenna apertures which are not arranged in a common plane, to form a 3D antenna.

13. Modular antenna array according to claim 1, wherein the at least one unbundling component for guiding the electromagnetic wave comprises at least one waveguide, wherein the unbundling component for guiding a plurality of electromagnetic waves originating from the printed circuit board comprises a plurality of waveguides whose guide channels in the unbundling component are not connected to each other.

14. Modular antenna array according to claim 13, wherein the unbundling component is configured to unbundle the plurality of electromagnetic waves emitted from the printed circuit board in a first predetermined area region and to guide them to a second predetermined area region which is larger in area than the first predetermined area region.

15. Modular antenna array according to claim 1, wherein the printed circuit board is configured to generate a clock signal and to pass it on to the unbundling component.

16. Modular antenna array according to claim 3, wherein the alignment means is at least one through-hole in the unbundling component and the printed circuit board, which are aligned with one another in a mounted state and through which a dowel pin can be inserted.

17. Modular antenna array according to claim 4, wherein the through-hole is aligned with a through-hole in the printed circuit board.

18. Modular antenna array according to claim 5, wherein at least one printed circuit board antenna is arranged as a chipset antenna integrated in the chipset in the form of a waveguide junction.

19. Modular antenna array according to claim 1, wherein the modular antenna array is a modular MIMO antenna array.

20. Modular antenna array according to claim 2, wherein the printed circuit board is configured to pass on to the unbundling component via a waveguide provided in the unbundling component for passing it on to a component that can be attached to the unbundling component.
